(19) United States
(12) Patent Application Publication
(10) Pub. No.: US 2026/0051029 A1
(43) Pub. Date: Feb. 19, 2026

(54) METHOD OF DETERMINING ABERRATIONS OF A CHARGED PARTICLE BEAM, METHOD OF DETERMINING CD INFORMATION, CORRESPONDING GENERATION OF COMPUTATIONAL MODELS, AND CORRESPONDING SYSTEMS

(71) Applicant: ICT Integrated Circuit Testing Gesellschaft für Halbleiterprüftechnik mbH, Heimstetten (DE)

(72) Inventors: Dominik Ehberger, Ebersberg (DE); John Breuer, Munich (DE); Ran Yacoby, Jerusalem (IL); Mor Baram, Ness Zionna (IL)

(73) Assignee: ICT Integrated Circuit Testing Gesellschaft für Halbleiterprüftechnik mbH, Heimstetten (DE)

(21) Appl. No.: 18/803,314

(22) Filed: Aug. 13, 2024

(51) Int. Cl. G06T 5/60; G06N 20/00; G06T 5/50; G06T 5/80; G06T 7/00; H01J 37/24

(52) U.S. Cl. CPC G06T 5/60; G06N 20/00; G06T 5/50; G06T 5/80; G06T 7/0004; H01J 37/24; G06T 2207/10061; G06T 2207/20081; G06T 2207/30148; G06T 2207/30168

(57) ABSTRACT

A method of generating a computational model for determining one or more aberration coefficients of a charged particle beam focused by a focusing lens towards a specimen is described. The method includes obtaining a plurality of input data associated with a plurality of beam spot information for a plurality of defocus settings; obtaining a plurality of one or more aberrations coefficients associated with corresponding input data of the plurality of input data; providing a training data set including the plurality of aberrations coefficients and the corresponding input data; and producing or generating the computational model by machine learning from the training data set. The computational model is also used for determining one or more aberration coefficients.

### TECHNICAL FIELD

Embodiments described herein relate to methods of determining aberrations of a charged particle beam in a charged particle beam system, for example in an electron microscope, particularly in a scanning electron microscope (SEM). Specifically, actual values of one or more beam aberration coefficients can be determined, facilitating the correction of the beam aberrations and improving the resolution. Further, computation models for determining aberrations are generated. More specifically, embodiments described herein relate to methods of determining beam aberration coefficients of a charged particle beam focused by a focusing lens, e.g. with a given numerical aperture toward a sample in a charged particle beam system, which facilitates the provision of an aberration-corrected charged particle beam and methods of generating a computational model for determining aberrations of a charged particle beam focused by a focusing lens towards a specimen. Embodiments further relate to charged particle beam systems for inspecting and/or imaging a sample that is configured for any of the methods described herein.

### BACKGROUND

Modern semiconductor technology has created a high demand for structuring and probing specimens in the nanometer or even in the sub-nanometer scale. Micrometer and nanometer-scale process control, inspection or structuring, is often done with charged particle beams, e.g. electron beams, which are generated, shaped, deflected and focused in charged particle beam systems, such as electron microscopes or electron beam pattern generators. For inspection purposes, charged particle beams offer a superior spatial resolution compared to, e.g., photon beams.

Inspection apparatuses using charged particle beams such as scanning electron microscopes (SEM) have many functions in a plurality of industrial fields, including, but not limited to, inspection of electronic circuits, exposure systems for lithography, detecting systems, defect inspection tools, and testing systems for integrated circuits. In such particle beam systems, fine beam probes with a high current density can be used. For instance, in the case of an SEM, the primary electron beam generates signal particles like secondary electrons (SE) and/or backscattered electrons (BSE) that can be used to image and/or inspect a sample.

Reliably inspecting, imaging samples, and/or critical dimensioning (CD) measurements with a charged particle beam system at a good resolution is, however, challenging because the charged particle beam typically suffers from beam aberrations that limit the obtainable resolution. In typical charged particle beam systems, aberration correctors are provided for at least partially compensating aberrations of the charged particle beam, such as spherical aberrations, astigmatism, and/or chromatic aberrations. An aberration-corrected charged particle beam can provide a smaller probe focus and hence a better resolution as compared to an uncorrected beam. However, it is challenging to appropriately adjust the settings of aberration correctors, which may have a large number of controls, such as to correct the beam aberrations satisfactorily, the reason being that the beam aberration that is present in the system is generally unknown.

Several methods for determining or correcting aberrations of a charged particle beam in electron microscopes have been described. For example, Uno et al. in “Aberration correction and its automatic control in scanning electron microscopes” (Optik—International Journal for Light and Electron Optics, 116(9) (2005) 438-448), hereinafter referred to as “UNO”, describes a method of determining dependencies between so-called “digitized aberrations” and field strengths of a specific multi-stage aberration corrector suitable for compensating such “digitized aberrations”. However, the aberration correction method of UNO is time-consuming, because a plurality of measurements has to be carried out for determining the mentioned dependencies, and the use of the determined dependencies is then limited to one specific multi-stage aberration corrector that is adapted for generating the respective field strengths.

In view of the above, it would be beneficial to provide methods of accurately and/or quickly and reliably determining aberrations of a charged particle beam focused by a focusing lens in a charged particle beam system, in particular for determining the actual values, i.e. numerical values rather than relative values, of beam aberration coefficients, i.e. the beam aberration coefficients in absolute values. Further, it would be beneficial to provide a charged particle beam system for inspecting and/or imaging a sample that is configured for being operated in accordance with any of the methods described herein. The determined actual aberration values can be used, for example, for correcting the charged particle beam and/or for examining the spot shape of the actual charged particle beam, e.g. for comparing performances between different charged particle beam tools.

Further, it is desirable to have measurements of critical dimensions on a specimen, particularly on different tools (different SEMs), to be improved based on aberrations and, even more particularly, based on different aberrations of the different tools.

### SUMMARY

In light of the above, a method of generating a computational model for determining aberrations of a charged particle beam, methods of determining beam aberrations of a charged particle beam and charged particle beam systems configured to determine beam aberrations of a charged particle beam, methods of generating a computation model for a CD measurement, and methods of determining CD information of a charged particle beam image are provided according to the independent claims.

According to an embodiment, a method of generating a computational model for determining one or more aberration coefficients of a charged particle beam focused by a focusing lens towards a specimen is provided. The method includes obtaining a plurality of input data associated with a plurality of beam spot information for a plurality of defocus settings; obtaining a plurality of one or more aberrations coefficients associated with corresponding input data of the plurality of input data; providing a training data set including the plurality of aberrations coefficients and the corresponding input data; and producing or generating the computational model by machine learning from the training data set.

According to an embodiment, a method of determining one or more aberration coefficients of a charged particle beam focused by a focusing lens towards a specimen is provided. The method includes providing a plurality of images of a defocus series, the images are of a charged particle beam device; providing the plurality of images or a plurality of beam spot data retrieved from the plurality of images in a computational model associating the defocus series with one or more aberration coefficients, the computation model being generated by machine learning; and obtaining one or more aberrations coefficients from the computational model.

According to an embodiment, a method of generating a computation model for a CD measurement is provided. The method includes obtaining a plurality of CD images; obtaining a plurality of aberration spot information; obtaining a plurality of sets of parameters; obtaining a plurality of CD correlation information; generating a training data set from the plurality CD images, the plurality of aberration spot information, the plurality of sets of parameters, and the plurality of CD information; and producing or generating the computational model by machine learning from the training data set.

According to an embodiment, a method of determining CD information of a charged particle beam image is provided. The method includes generating an image of a specimen with a charged particle beam device; obtaining one or more aberration coefficients; obtaining a set of parameters; and generating CD results from a computational model with the image, the one or more aberration coefficients, and the set of parameters as an input for the computational model.

According to an embodiment, a system for calculating one or more aberration coefficients is provided. The system includes a memory comprising instructions; and a processor executing the instructions to determine aberration coefficients with a method of any of the embodiments described herein.

According to an embodiment, a system for calculating CD information is provided. The system includes a memory comprising instructions; and a processor executing the instructions to determine aberration coefficients with a method of any of the embodiments described herein.

Embodiments are also directed at apparatuses for carrying out the disclosed methods and include apparatus parts for performing the individual method actions. The method may be performed by way of hardware parts, a computer programmed by appropriate software, by any combination of the two or in any other manner. Furthermore, embodiments are also directed at methods of operating the described apparatuses.

Further advantages, features, aspects and details that can be combined with embodiments described herein are evident from the dependent claims, the description and the drawings.

### BRIEF DESCRIPTION OF THE DRAWINGS

So that the manner in which the above recited features of the present disclosure can be understood in detail, a more particular description, briefly summarized above, may be had by reference to embodiments. The accompanying drawings relate to one or more embodiments and are described in the following.

FIG. 1 shows a schematic view of a charged particle beam system according to embodiments described herein that is adapted for being operated according to any of the methods described herein;

FIG. 2 shows a diagram illustrating input in a neural network for generating a computational model according to embodiments of the present disclosure;

FIG. 3 shows a flow chart illustrating method of generating a computational model according to some embodiments of the present disclosure;

FIG. 4 illustrates a generalized model of a neural network usable with embodiments of the present disclosure;

FIG. 5 illustrates a functional block diagram of data processing and control in a manufacturing fab equipment in accordance with embodiments of the present disclosure;

FIG. 6 shows a diagram illustrating input in a neural network for determining one or more aberration coefficients according to embodiments of the present disclosure and output of a neural network;

FIG. 7 shows a flow chart illustrating method of determining one or more aberration coefficients according to some embodiments of the present disclosure

FIG. 8 shows the results of training, validation and test for determining aberrations according to embodiments of the present disclosure; and

FIG. 9 shows a diagram illustrating input in a neural network for CD measurement according to embodiments of the present disclosure and output of the neural network for embodiments of the present disclosure.

### DETAILED DESCRIPTION

Reference will now be made in detail to the various embodiments, one or more examples of which are illustrated in the figures. Within the following description of the drawings, same reference numbers refer to same components. Generally, only the differences with respect to individual embodiments are described. Each example is provided by way of explanation and is not meant as a limitation. Further, features illustrated or described as part of one embodiment can be used on or in conjunction with other embodiments to yield yet a further embodiment. It is intended that the description includes such modifications and variations.

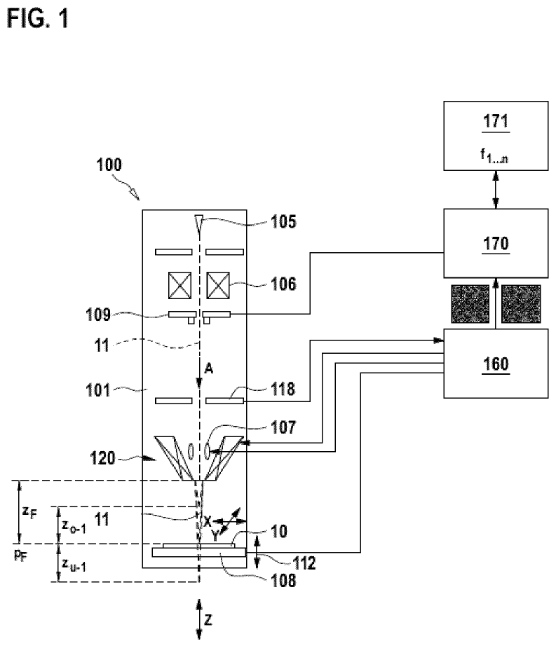

FIG. 1 is a schematic view of a charged particle beam system 100 for inspecting and/or imaging a sample 10 according to embodiments described herein. The charged particle beam system 100 includes a charged particle source 105, particularly an electron source, for emitting a charged particle beam 11, particularly an electron beam, propagating along an optical axis A. The charged particle beam system 100 further includes a sample stage 108, and a focusing lens 120, particularly an objective lens, for focusing the charged particle beam 11 on the sample 10 that is placed on the sample stage 108. The charged particle beam system 100 further includes a charged particle detector 118, particularly an electron detector, for detecting signal particles (particularly secondary electrons and/or backscattered electrons) emitted from the sample 10.

An image generation unit 160 may be provided that is configured to generate one or more images of the sample 10 based on the charged particle signal received from the charged particle detector 118. The image generation unit 160 can forward the one or more images of the sample to a processing unit 170 that is configured to determine actual values of beam aberration coefficients therefrom in accordance with the methods described herein.

The sample stage 108 may be a movable stage. In particular, the sample stage 108 may be movable in the Z-direction, i.e., in the direction of the optical axis A, such that the distance between the focusing lens 120 and the sample stage 108 can be varied (see arrow 112 in FIG. 1). By moving the sample stage 108 in the Z-direction, the sample 10 can be moved to different “defocus distances” away from a focal plane pr of the focusing lens 120 such that out-of-focus images of the sample 10 can be taken by a respective stage movement, e.g. in increments of, e.g. 0.1 μm or more, and/or 2 μm or less. In some embodiments, the sample stage 108 may also be movable in a plane perpendicular to the optical axis A (also referred to herein as the X-Y-plane). By moving the sample stage 108 in the X-Y-plane, a specified surface region of the sample 10 can be moved into an area below the focusing lens 120, such that the specified surface region can be imaged by focusing the charged particle beam 11 thereon.

The beam-optical components of the charged particle beam system 100 are typically placed in a vacuum chamber 101 that can be evacuated, such that the charged particle beam 11 can propagate along the optical axis A from the charged particle source 105 toward the sample stage 108 and hit the sample 10 under a sub-atmospheric pressure, e.g. a pressure below 10-3 mbar or a pressure below 10-5 mbar.

In some embodiments, the charged particle beam system 100 may be an electron microscope, particularly a scanning electron microscope. A scan deflector 107 may be provided for scanning the charged particle beam 11 over a surface of the sample 10 along a predetermined scanning pattern, e.g., in the X-direction and/or in the Y-direction.

In some embodiments, a condenser lens system 106 may be arranged downstream of the charged particle source 105, particularly for collimating the charged particle beam 11 propagating toward the focusing lens 120. In some embodiments, the focusing lens 120 is an objective lens configured to focus the charged particle beam 11 on the sample 10, particularly a magnetic objective lens, an electrostatic magnetic lens, or a combined magnetic-electrostatic lens.

One or more surface regions of the sample 10 can be inspected and/or imaged with the charged particle beam system 100. The term “sample” as used herein may relate to a substrate, e.g., with one or more layers or features formed thereon, a semiconductor wafer, a glass substrate, a flexible substrate, such as a web substrate, or another sample that is to be inspected. The sample can be inspected for one or more of (1) imaging a surface of the sample, (2) measuring dimensions of one or more features of the sample, e.g. in a lateral direction, i.e. in the X-Y-plane, (3) conducting critical dimension measurements and/or metrology, (4) detecting defects, and/or (5) investigating the quality of the sample.

For inspecting the sample 10 with the charged particle beam 11, the charged particle beam 11 is typically focused on a sample surface with the focusing lens 120. Secondary electrons and/or backscattered electrons (referred to as “signal electrons”) are emitted from the sample when the charged particle beam 11 impinges on the sample surface. The signal electrons provide information about spatial characteristics and dimensions of features of the sample, and can be detected with the charged particle detector 118. By scanning the charged particle beam 11 over the sample surface, e.g. with the scan deflectors 107, and detecting the signal electrons as a function of the generation position of the signal electrons, the sample surface or a portion thereof can be imaged, e.g., with the image generation unit 160 that may be configured to provide an image of the sample 10 based on the received signal electrons.

A small spot of the focused charged particle beam 11 on the sample surface increases the obtainable image resolution. Accordingly, the sample surface should be arranged in the focal plane pr of the focusing lens 120 during the inspection, in order to obtain a sharp in-focus image of the sample 10. A sharp image of the sample 10 taken in-focus is also referred to herein as a “focus image h_{F}”, the subscript F designating “Focus”, whereas an image taken out-of-focus is referred to herein as a defocus image, such as an over-focused image hₒ₋₁ taken behind the beam focus or an under-focused image hᵤ₋₁ taken in front of the beam focus.

Further to an image, a cross section of the beam can be evaluated, e.g. the cross-section of the beam on the sample surface. Similarly, the beam cross section of the charged particle beam 11 in the focal plane pr is referred to herein as a “focus beam cross section g_{F}”, whereas the beam cross section out of focus is referred to herein as a defocus beam cross section, such as an over-focused beam cross section gₒ₋₁ behind the beam focus or an under-focused beam cross section gᵤ₋₁ in front of the beam focus.

Notably, an image can be mathematically presented in real space (=in the image domain, i.e. as a function of the spatial coordinates) or in Fourier space (=in the frequency domain, i.e. as a function of spatial frequency). An image in Fourier space can be calculated from an image in real space via a Fourier transformation (FT). Both above representations contain corresponding information of the image. As used herein, images in real space are designated with the small letter “hₙ” and images in Fourier space are designated by the capital letter “Hₙ”. For example, while “h_{F}” designates the focus image of the sample in real space, “H_{F}” designates the focus image of the sample in Fourier space, which is a Fourier transform of h_{F}. Similarly, beam cross sections in real space are designated herein with the small letter “gₙ”, and beam cross sections in Fourier space are designated herein by the capital letter “Gₙ”. For example, while “g_{F}” designates the focus beam cross section of the charged particle beam in real space, “G_{F}” designates the focus beam cross section of the charged particle beam in Fourier space, which is a Fourier transform of gr. Images and beam cross sections in real space can be Fourier transformed into Fourier space, and vice versa, via a fast Fourier transform (FFT) algorithm in some of the embodiments described herein.

Simulated images and simulated beam cross sections are designated herein with a tilde above the respective letter, such as (\tilde{h}_{1 . . . N}) for simulated images and (\tilde{g}_{1 . . . N}) for simulated beam cross sections. Actual images taken by the charged particle beam system and beam cross sections retrieved from the actually taken images are designated herein without a tilde above the respective letter, such as (h_{1 . . . N}) for taken images and (g_{1 . . . N}) for beam cross sections retrieved therefrom.

In charged particle beam systems, beam aberrations typically lead to an enlarged or deformed beam cross section, which reduces the achievable resolution. For example, spherical aberrations in the system which are typically introduced by lenses lead to an enlarged focus beam cross section in the focal plane p_{F}, and astigmatism may lead to different foci for rays propagating in different planes, which blurs the image.

Different types of beam aberrations may be present in a charged particle beam system and may need correction, such as, for example, (1) spherical aberration (quantitatively expressed by the beam aberration coefficient C_{3,0} or Cₛ), (2) defocus (quantitatively expressed by the beam aberration coefficient C_{df} or C1,0), (3) astigmatism of the 1^{st} order (quantitatively expressed by the beam aberration coefficient C1,2 or Cast-2 fold), (4) astigmatism of the 2^{nd} order (quantitatively expressed by the beam aberration coefficient C2,3 or Cast,3-fold), (5) astigmatism of the 3^{rd} order (quantitatively expressed by the beam aberration coefficient C3,4 or Cast,4-fold), (6) coma (quantitatively expressed by the beam aberration coefficient Ccoma), (7) star aberration (quantitatively expressed by the beam aberration coefficient C3,2 or Cstar), and chromatic aberration (quantitatively expressed by the beam aberration coefficient Cc).

Further, a plurality of chromatic aberrations may be present, depending on the energy spread of the charged particle beam and on the dispersion of the beam-optical components of the system, which can be quantitatively expressed by one or more chromatic aberration coefficients.

A set of beam aberration coefficients C_{1 . . . n} may include two, three or more of the above beam aberration coefficients, for example C_{1 . . . n}=[C_{df}, Cₛ, C1,2, C2,3]. The absolute values of the beam aberration coefficients of the set of beam aberration coefficients C_{1 . . . n} may be determined for the actual charged particle beam that is present in the charged particle beam system, according to embodiments and methods described herein, such that the beam aberrations can be compensated with one or more beam aberration correctors that are adjusted in accordance with the determined absolute values.

Beam aberrations can be corrected with aberration correctors, for example with electrostatic or magnetic multipole correctors. An aberration corrector 109 is schematically depicted in FIG. 1, but it is to be understood that the charged particle beam system may also include two or more aberration correctors that are not necessarily provided at one position along the optical axis A. For example, a stigmator including a quadrupole may be provided for correcting 1ₛₜ-order astigmatism C1,2, and/or higher order multipoles may be provided for correcting higher-order astigmatism C2,3 and/or C3,4. Further correctors may be provided for compensating spherical aberration Cₛ. Various types of aberration correctors for correcting various beam aberrations coefficients are known.

It is challenging to adjust an aberration corrector such that one or more types of beam aberration are appropriately corrected, the reason being that the amount of beam aberration that is present in the system is generally unknown. It is possible to set one or more aberration correctors such that pre-calculated beam aberrations that are theoretically introduced by the beam-optical components of the system are compensated, but such an approach is typically not sufficiently accurate. Specifically, not all the sources of beam aberrations are known, in particular quantitatively. For example, beam aberrations may also be introduced by inaccuracies of the system, such as mechanical, magnetic or electrostatic inaccuracies, charge contamination, material inhomogeneities, fabrication imperfections, which are not initially known. Beam-optical components may include one or more of an objective lens, a collimator, a deflector, a scan deflector, a beam separator, a charged particle detector, and an aberration corrector.

Various methods can be used for estimating beam aberrations in a charged particle beam system, such that the beam aberrations can be at least partially corrected. Some methods rely on the visible inspection of the charged particle beam, e.g. in the far-field, which may give an indication of aberrations that are present in the system. Other methods rely on the analysis of taken images. An image that is taken out of focus yields information about the respective beam cross section (i.e., the probe shape) out of focus, and the probe shape out of focus can give qualitative information about specific types of beam aberrations. For example, astigmatic beams are typically non-rotationally symmetric, in particular at positions distant from the beam focus. Methods rely on the extraction of line profiles from a defocus beam cross section, and beam aberrations can be estimated from such line profiles.

UNO describes in sections 6 and 6.1 the extraction of beam cross sections (i.e., probe shapes) from images taken out of focus, and in section 6.2 the determination of “digitized aberrations” from under-focused and over-focused probe shapes. The digitized aberrations can be retrieved from over-focused and under-focused beam cross sections and can be defined for different beam aberrations, see formulas (38)-(47) of UNO. UNO is incorporated herein by reference, particularly with respect to the determination of “digitized aberrations” (herein referred to as “aberration characteristics”) from defocus beam cross sections and with respect to the determination of defocus beam cross sections (in particular, under-focused and over-focused beam cross sections) from images taken out of focus (UNO, chapter 6).

According to UNO, a plurality of measurements is carried out for determining dependencies between the digitized aberrations and correction fields applied by a specific beam aberration corrector. The determined dependencies are then related to a specific multi-stage aberration corrector that is adapted for generating the respective field strengths, which makes the method of UNO time consuming and its field of application limited.

The above concepts allow only for relative estimates of aberrations, whereas no absolute values of aberration coefficients can be retrieved. “Absolute values” of beam aberration coefficients may be understood as the actual quantitative values of the beam aberration coefficients, such as Cₛ expressed in [mm], which values directly allow an appropriate setting of an aberration corrector based on the determined absolute values of the beam aberration coefficients. An absolute value is a numerical value, which can be positive or negative. Notably, previously known methods typically only enable relative estimates of beam aberrations that may vary from measurement to measurement and/or that relate to the specific correction fields generated by a specific aberration corrector.

Methods described herein allow for the accurate and reliable determination of actual values of beam aberration coefficients quantitatively describing the beam aberrations of a charged particle beam. In some embodiments, the actual values of the beam aberration coefficients may be determined with a processing unit 170 and can then be directly forwarded to the aberration corrector 109, such that the aberration corrector 109 can compensate one or more of the beam aberrations, and an aberration-compensated charged particle beam can be provided.

Embodiments of the present disclosure allow to determine beam aberrations. This allows to reduce or minimize, either by design or correctors, aberrations. Further, knowledge of existing aberrations, e.g. in form of aberration coefficients, in a single SEM can be used to match, specify and/or qualify the tool with respect to a fleet of ideally identical systems. Providing the aberration characteristics of one tool with respect to other tools in a fleet of tools is referred to as matching. Embodiments of the present disclosure allow to compare the tool's aberration coefficients and related quantities, such as numerical aperture, in absolute values for matching. According to some embodiments, different tools in a fleet of tools, i.e. different SEMs, may be of identical type.

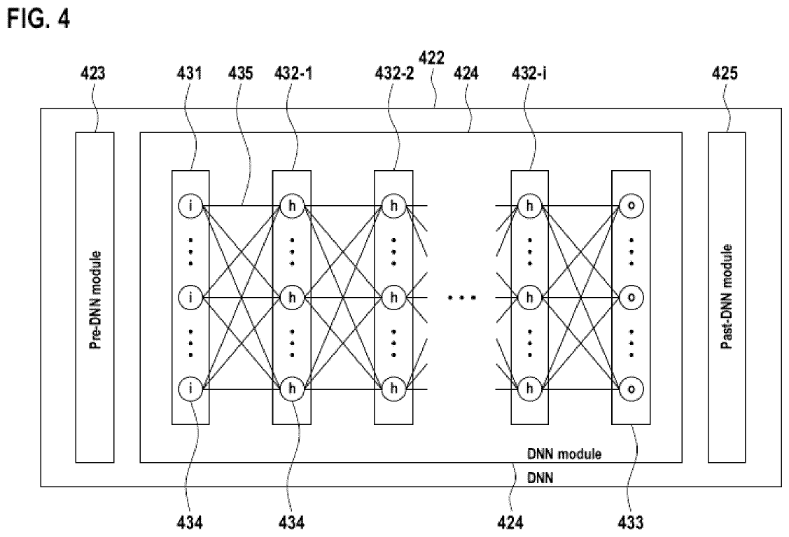

Embodiments of the present disclosure provide methods for a holistic beam characterization. The methods are based on machine learning models, for example, deep learning models, of aberrational features of spots or images. Embodiments relate to training and/or determining aberration coefficients based on a trained model. Training can be provided either with simulated data or real data of known aberrations. According to some embodiments, the models, e.g. neural network, can be extended and be applied for tool matching applications. For example, the neural network can be a CNN or another DNN as exemplarily illustrated in FIG. 4.

According to an embodiment, a method of generating a computational model for determining one or more aberration coefficients of a charged particle beam focused by a focusing lens towards a specimen is provided. The method includes obtaining a plurality of input data associated with a plurality of beam spot information for a plurality of defocus settings and obtaining a plurality of one or more aberrations coefficients associated with corresponding input data of the plurality of input data. A training data set including the plurality of aberrations coefficients and the corresponding input data is provided. The method further includes producing or generating the computational model by machine learning from the training data set. For example, the training may include determination of weights in a neural network, and particularly in a convolutional neural network, as described in more detail below.

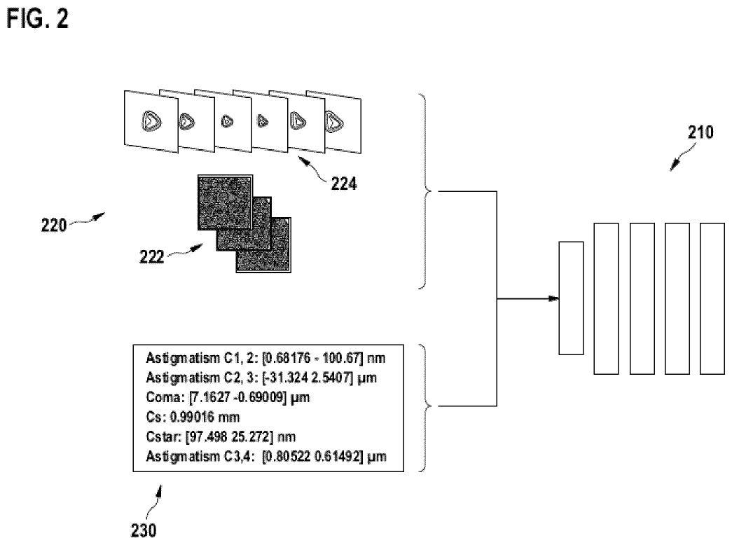

FIG. 2 shows a schematic diagram for generating a computational model. A plurality of data sets are provided. Each data set includes input data associated with a plurality of beam spot information for a plurality of defocus settings. FIG. 2 exemplarily shows one data set. The input data 220 can be images 222 of a defocus series or beam spot data 224 of a defocus series. For example, images can be generated by measuring signal electrons with a charged particle beam detector 118 (see FIG. 1). An image generation unit 160 may be provided that is configured to generate one or more images of the sample 10 based on the signal electrons received from the charged particle detector 118. For example, beam spot data, e.g. beam cross sections, can be generated from images. Beam spot data may also be simulated. The input data includes beam spot information in any of the forms described herein for a defocus series, i.e. a plurality of defocus settings. For example, the beam spot information can be provided by an image or can be retrieved from an image. The beam spot information can be provided by beam spot data. i.e. beam spot cross-sections in 2D, or line profiles of the beam spots. Yet, further, the characteristics of a beam spot data may be retrieved and utilized, such as width, curvature, symmetry or the like.

Accordingly, the input data provides beam spot information. For each input data 220 one or more aberrations coefficients 230 are provided, wherein the one or more aberration coefficients, i.e. each set of aberration coefficients, correspond to the input data. The one or more aberrations coefficients are known, are determined from the input data by another method, or are simulated from the input data or together with the input data. A plurality of input data and a plurality of corresponding one or more aberrations coefficients form a training data set that is provided to, e.g. a neural network 210 for training of the neural network. A computational model is produced or generated by machine learning from the training data set.

In some embodiments, the one or more first defocus settings may include one or more defocus distances (zₒ₋₁, zᵤ₋₁), see e.g. FIG. 1, from the beam focus of the charged particle beam. If beam aberrations are present in a charged particle beam, such beam aberrations appear much more clearly at defocus distances than in the focal plane, e.g., because the focal spot is very small. Therefore, aberration characteristics can be retrieved more reliably and more accurately from defocus beam spot information, e.g. defocus beam cross sections, as compared to focus beam spot information, e.g. focus beam cross sections. The one or more defocus distances may include a pair of defocus distances, namely an overfocus distance (zₒ₋₁) and an underfocus distance (zᵤ₋₁). In other words, the beam spot information may be obtained on both sides of the beam focus, particularly at a corresponding positive and negative distance from the beam focus, referred to herein as an overfocus distance and an underfocus distance.

The defocus distance can be varied by varying a focusing strength of the focusing lens 120, e.g. in predetermined increments (as it is schematically illustrated in FIG. 1). Specifically, an increased focusing strength of the focusing lens 120 shifts the respective beam focus and the focal plane relative to the sample toward the focusing lens, and a decreased focusing strength shifts the respective beam focus and the focal plane relative to the sample away from the focusing lens, such that the defocus distance is varied. Alternatively or additionally, the defocus distance can be varied by moving the sample stage 108, e.g., in predetermined increments, particularly in the Z-direction (along the optical axis A), in particular while maintaining a constant focal strength provided by the focusing lens 120.

In some embodiments, a plurality of two, three, six or more images may be taken at two, three, six or more different defocus distances between the sample and the respective beam focus. Specifically, at least one image of the sample may be taken at an overfocus distance, i.e. at a defocus setting in which the sample is arranged further away from the focusing lens 120 than the beam focus of the charged particle beam (see defocus distance z1 illustrated in FIG. 1). Further, at least one image of the sample may be taken at an underfocus distance, i.e. at a defocus setting in which the sample is arranged closer to the focusing lens 120 than the respective beam focus of the charged particle beam (see defocus distances z2 . . . N illustrated in FIG. 1). An image taken at the first defocus distance z1 is designated herein as a taken image h1, and an image taken at the nth defocus distance Zn is designated herein as taken image hₙ. A total of N images may be taken, designated as (h1 . . . N).

According to embodiments, which can be combined with other embodiments described herein, defocus areas may also include a focus image or other beam spot information, for which the beam is in focus, i.e. at the focus distance z_{F}.

Alternatively or additionally, the one or more defocus settings may include one or more beam landing energies of the charged particle beam varied from the focus beam landing energy EL. The focus beam landing energy EL can be understood as the beam landing energy of the actual charged particle beam system, which provides a beam focus on the sample, such that the sample is arranged in focus, and a variation away from said focus beam landing energy leads to a defocus setting (“energy defocus”), i.e. a shift of the beam focus into another plane. Therefore, a varied beam landing energy leads different focus distances. In some embodiments, which can be combined with other embodiments described herein, the one or more defocus settings may include taking images at one or more beam landing energies (E1 . . . N) of the charged particle beam 11 that are varied from the focus beam landing energy. A focus beam landing energy EI can be understood as a beam landing energy which provides a beam focus on the sample, such that one or more images of the sample are taken off-focus at the one or more varied beam landing energies.

In some embodiments, the one or more defocus settings may include one or more different defocus distances (z1 . . . N) of the sample and one or more different beam landing energies (E1 . . . N) of the charged particle beam. If images are not only taken at one or more varied defocus distances, but also at one or more varied defocus energies, this may facilitate the reliable and accurate determination not only of the “geometric” beam aberration coefficients, such as astigmatism and spherical aberration, but also of one or more “chromatic” aberration coefficients.

According to some embodiments, which can be combined with other embodiments described herein, the input data can be based on images obtained by the charged particle beam device. Accordingly, the beam spot information of a defocus series can be provided by images of defocus series. The images can be provided as part of the training data set and the computational model can be produced or generated based upon the images.

According to some embodiments, which can be combined with other embodiments described herein, the plurality of images of defocus series, i.e. images of a plurality of defocus series, can be provided as input data and beam spot data can be retrieved from the images.

According to some embodiments, which can be combined with other embodiments described herein, the input data can be provided by a plurality of images and/or a plurality of beam spot data.

Beam spot data or beam cross sections (gₒ₋₁, gᵤ₋₁) are retrieved from the one or more taken images (h_{1 . . . N}). Out-of-focus beam profiles can be extracted from out-of-focus images via several different profile extraction methods. Accordingly, if an under-focused image and an over-focused image of the sample are taken, an under-focused retrieved beam cross section (gᵤ₋1) or beam spot data is retrieved from the under-focused image, and an over-focused retrieved beam cross section (gₒ₋1) or bam spot data is retrieved from the over-focused image.

In some embodiments, which can be combined with other embodiments described herein, retrieving the one or more retrieved beam cross sections from the one or more images includes dividing the one or more images in Fourier space by a focus image of the sample in Fourier space. Alternatively, the retrieval of the one or more retrieved beam cross sections (gₒ₋₁, gᵤ₋₁) from the one or more images (hₒ₋₁, hᵤ₋₁) may be conducted in real space, particularly based on a deconvolution in real space, which is equivalent to a division in Fourier space.

Retrieving the one or more beam cross sections (gₒ₋₁, gᵤ₋₁) from the one or more images (hₒ₋₁, hᵤ₋₁) may specifically include Fourier transforming the one or more taken images in real space (hₒ₋₁, hᵤ₋₁) to provide the one or more taken images in Fourier space (Hₒ₋₁, Hᵤ₋₁), and dividing the one or more taken images in Fourier space (Hₒ₋₁, Hᵤ₋₁) by the focus image of the sample in Fourier space (H_{F}). Said beam profile extraction method is based on the fact that, in Fourier space, dividing a taken defocus image (Hₒ₋₁) of a sample by the focus image (H_{F}) of the sample removes the structure of the sample, such that said division yields the pure beam profile (Gₒ₋₁), i.e. the beam cross section without sample information. The retrieved beam cross sections or beam spot data in Fourier space can then be inversely Fourier transformed for obtaining the one or more retrieved beam cross sections (gₒ₋₁, gᵤ₋₁) or beam spot data in real space.

Retrieving the one or more retrieved beam cross sections (gₒ₋₁, gᵤ₋₁) from the one or more taken images (hₒ₋₁, hᵤ₋₁) may optionally include the application of a filter, in particular a multiplication with an adaptive filter term G_{o-1,u-1}^{Filter}, if the retrieval is done in Fourier space, or a convolution with an adaptive filter term, if the retrieval is done in real space. The adaptive filter term can be provided by an adaptive filter unit that may receive the taken images as an input information. An adaptive filter term may be provided individually for each of the taken images by the adaptive filter unit. Without the adaptive filter term, close-to-zero values of the focus image H_{F} in the denominator of the above division may lead to an overly strong weight of noise in the image. The adaptive filter term reduces or avoids such unwanted effects of noise in the focus image H_{F} in the calculation of the one or more retrieved beam cross sections or beam spot data, and a respective filter term may be determined in the adaptive filter unit for each of the taken images individually. Alternatively or additionally to the application of the adaptive filter term, retrieving the one or more retrieved beam cross sections or beam spot data from the one or more taken images may include a multiplication with a focus beam cross section in Fourier space G_{F}.

A calculation of the beam spot data, i.e. the beam cross sections, can be provided in a processing unit, such as the processing unit 170 shown in FIG. 1. The beam spot data calculated from the images can be used in the training data set for producing or generating the computational model. Accordingly, images can be used as input data and the machine learning is provided by beam spot data retrieved from the images.

According to some embodiments, which can be combined with other embodiments described herein, the plurality of input data can be a plurality of images of defocus series. The images are from a charged particle beam device, such as a SEM. Optionally, the plurality of input data can be a plurality of images of defocus series to obtain the plurality of beam spot information from the plurality of images. For example, the plurality of images are converted into a plurality of beam spot data with a deconvolution operation. As another example, the plurality of images are converted into a plurality of beam spot data by dividing images of the plurality of images in the Fourier space. A conversion of the images may be provided in a pre-deep neural network (DNN) module 423 (see FIG. 4) or can be provided, for example, by a software external to the DNN, such that the the converted input data is provided to the DNN.

According to yet further embodiments, which can be combined with other embodiments described herein, the beam spot data, i.e. beam cross sections of defocus series can be obtained from an external source, and particularly in combination with corresponding sets of one or more aberration coefficients, i.e. a plurality of one or more aberration coefficients associated with corresponding input data of the plurality of input data.

According to some embodiments, which can be combined with other embodiments described herein, the beam spot data can, for example, be obtained by a simulation of beam cross sections for one or more aberration coefficients.

The one or more beam cross sections (go-1, gu-1) or beam spot data can be simulated at the one or more defocus distances (zo-1, zu-1) for a plurality of different values of one or more aberration coefficients to generate a training data set for the computational model. Specifically, the beam cross sections are simulated at positions away from the respective beam focus by certain positive and/or negative distances (z≠0), such that the plurality of first simulated beam cross sections are out-of-focus beam cross sections. In particular, an over-focused beam cross section and an under-focused beam cross section may be simulated for each of the two or more different values of a first beam aberration coefficient to provide the plurality of first simulated beam cross sections or simulated beam spot data.

Further, simulating the beam cross sections or beam spot data at the one or more varied beam landing energies is particularly beneficial, if a first beam aberration coefficient is a chromatic beam aberration coefficient, whereas simulating the beam cross section beam spot data at the one or more defocus distances is particularly beneficial, if the first beam aberration coefficient is a geometric beam aberration coefficient.

According to some embodiments, simulated images may be obtained, e.g. by simulating beam cross sections and convoluting the simulated beam cross-section with the information from the sample to obtain a simulated image.

A filter term G_{1 . . . N}^{Filter}, as described above, may also be applied to the respective simulated beam cross section (\tilde{g}_{1 . . . N}) or beam spot data, in order to allow a better comparison between the retrieved beam cross sections and the respective simulated beam cross sections.

According to some embodiments, which can be combined with other embodiments described herein, the plurality of beam spot data and the plurality of one or more aberration coefficients can be simulated.

For generating of a training data set, a plurality of input data is provided. Each input data includes beam spot information (e.g. images or beam spot data) of a defocus series. For each input data, i.e. each defocus series, a corresponding set of one or more aberrations coefficients is provided.

According to some embodiments, which can be combined with other embodiments described herein, a computational model can be generated for one aberration coefficient. One or more computational models can be generated for one aberration coefficient each. Alternatively, a computational model can be generated for a plurality of aberration coefficients, i.e. a set of aberration coefficients. Further, a combination of having a computational model for a first group (with a number of n>=1) of aberration coefficients and one or more second groups (with numbers of n>=1) of aberration coefficients can be provided.

In addition to having a variety of values of aberration coefficients in a training data set, a variety of charged particle beam parameters as discussed in more detail below, may also be provided in a training data set. According to some embodiments, which can be combined with other embodiments described herein, the computational model can be provided or generated by training with the training data set. For example, weights of a convolutional neural network can be calculated based on the training data set. The training may be completed after a loss function drops below a certain value or after exemplary input data (similar to the training data, but not used for training) allows determination of one or more aberration coefficients with a coefficient of determination between the true values and the predicted values that is above a certain threshold, e.g. 0.9 or even 0.99.

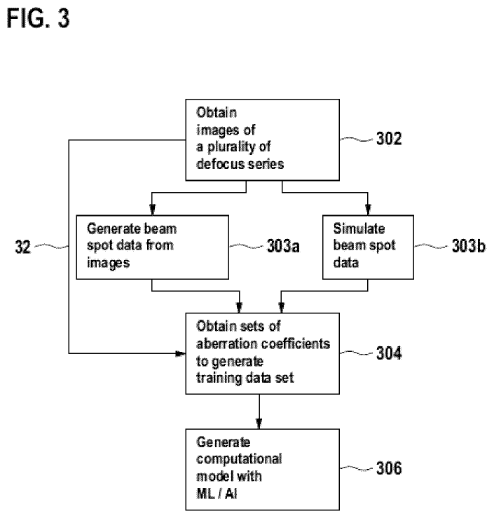

FIG. 3 shows a flow method of generating a computational model for determining one or more aberration coefficients of a charged particle beam. At operation 302 images are obtained. A plurality of sets of images are obtained. According to some embodiments, which can be combined with other embodiments described herein, the plurality of images are measured with a charged particle beam device.

The sets include a defocus series, i.e. images with different defocus settings. One or more images of the sample are taken at one or more defocus settings to provide one or more taken images (h1 . . . N), in particular by the image generation unit 160 (shown in FIG. 1). The one or more defocus settings may include one or more defocus distances (z1 . . . N) between the sample 10 and a respective beam focus of the charged particle beam. A defocus distance is understood herein as the distance (>0) between the sample and the beam focus when an image is taken. Specifically, the one or more images of the sample may be taken, when the sample is arranged at one or more defocus distances (z1 . . . N) from a respective beam focus of the charged particle beam (schematically depicted in FIG. 1), such that the one or more taken images (h1 . . . N) are out-of-focus images of the sample. Naturally, an increased defocus distance leads to an increased blurring of the respective taken image, because the probe size generally increases and the resolution generally decreases with the defocus distance.

From the images, beam spot data, for example, beam spot cross-sections, can be generated at operation 303a. Alternatively, beam spot data may be simulated (see, for example, operation 303b.) At operation 304, training data set is generated. The training data set includes sets of one or more aberration coefficients. Further, the training data set can include corresponding beam spot data. As indicated by arrow 32, generation of beam spot data can be optional and the images of the plurality of defocus areas may be utilized in the training data set. At operation 306 a computational model is generated from the training data set with machine learning and/or an artificial intelligence algorithm. For example, a neural network, such as a convolutional neural network, can be trained. A neural network is exemplarily shown in FIG. 4.

A generalized model of an exemplified deep neural network usable as DNN 422 is illustrated in FIG. 4. Even though FIG. 4 shows a DNN, i.e. a neural network with more than three layers, neural networks with a smaller number of layers might also be utilized. The below description referring to a DNN may similarly be applied to a neural network (NN) in general and other artificial intelligence (AI) computational models, particularly machine learning (ML) computational models.

Embodiments of the present disclosure can, for example, be realized with a convolutional neural network (CNN), i.e. a feedforward neural network as illustrated in FIG. 4. As described in more detail below, one or more layers can perform a convolution. A feature map can be generated. A deep neural network (DNN) without convolution would be based on pixels of the images or pixels of the beam spot data, i.e. larger input, such that having a deep network is more difficult in light of the number of pixels. The convolution reduces the number of parameters to be considered, such that a deep neural network can beneficially be utilized.

The illustrated exemplified DNN comprises DNN module 424 with input layer 431, output layer 433 and one or more hidden layers (denoted as 432-1 to 432-i) for an NN, or two or more hidden layers for a DNN, disposed between the input layer and the output layer. Optionally, DNN comprises pre-DNN module 423 and post-DNN module 425. For example, the first hidden layer 432-1 or further layers can perform the convolution to have a CNN according to some embodiments of the present disclosure. The first hidden layer (or another layer, typically close to the input layer) can be a convolution layer. Further, a second layer 432-2 (or another layer close to the convolution layer) can be a pooling layer, which can be utilized in combination with the convolution layer. According to some embodiments, also a strided convolution neural network might be applied, at which, for example, different pixels are skipped for each striding.

Each layer of DNN module 424 can include multiple basic computational elements (CE) 434 typically referred to in the art as dimensions, neurons, or nodes. CEs comprised in the input layer are denoted in FIG. 4 by letter “i”, Ces comprised in the hidden layers are denoted by letter “h”, and Ces comprised in the output layer are denoted by letter “o”. Computational elements of a given layer are connected with Ces of a subsequent layer by connections 435. Each connection 435 between CE of preceding layer and CE of subsequent layer is associated with a weighting value (for simplicity, not shown in FIG. 4).

A given hidden CE can receive inputs from Ces of a previous layer via the respective connections, each given connection being associated with a weighting value which can be applied to the input of the given connection. The weighting values can determine the relative strength of the connections and thus the relative influence of the respective inputs on the output of the given CE. The given hidden CE can be configured to compute an activation value (e.g. the weighted sum of the inputs) and further derive an output by applying an activation function to the computed activation. The activation function can be, for example, an identity function, a deterministic function (e.g., linear, sigmoid, threshold, or the like), a stochastic function or other suitable function. The output from the given hidden CE can be transmitted to Ces of a subsequent layer via the respective connections. Likewise, as above, each connection at the output of a CE can be associated with a weighting value which can be applied to the output of the CE prior to being received as an input of a CE of a subsequent layer. Further to the weighting values, there can be threshold values (including limiting functions) associated with the connections and Ces.

The weighting and/or threshold values of a (deep) neural network can be initially selected prior to training, and can be further iteratively adjusted or modified during training to achieve an optimal set of weighting and/or threshold values in the trained DNN module. After each iteration, a difference can be determined between the actual output produced by the DNN module and the target output associated with the respective training set of data. The difference can be referred to as an error value. Training can be determined to be complete when an error function or loss function indicative of the error value is less than a predetermined value or when a limited change in performance between iterations is achieved. Accordingly, based on input data associated with a plurality of beam spot information for a plurality of defocus settings and based on a plurality of formal aberration coefficients associated with corresponding input data of the plurality of input data, a computational model can be produced or generated, e.g. trained.

A set of DNN input data used to adjust the weights/thresholds of the deep neural network is referred to herein as a training data set. Inputs to DNN 422 can be pre-processed by a pre-DNN module 423 prior to inputting to DNN module 424 and/or outputs of DNN module 424 can be post-processed by post-DNN module 425 before outputting from DNN 422. In such cases, training of DNN 422 further includes determining parameters of the pre-DNN module and/or the post-DNN module. The DNN module can be trained so as to minimize loss function of the entire DNN, while parameters of the pre-DNN module and/or the post-DNN module can be predefined and, optionally, can be adjusted during the training. A set of training-based parameters can further include parameters related to pre-DNN and post-DNN processing.

According to some embodiments, which can be combined with other embodiments described herein, the pre-DNN module 423 may, for example, obtain a plurality of beam spot information from a plurality of images, particularly for embodiments, wherein images are used in the training data set for the DNN 422.

It is noted that the teachings of the presently disclosed subject matter are not bound by the number of hidden layers and/or by DNN architecture. By way of a non-limiting example, the layers in DNN can be convolutional, fully connected, locally connected, pooling/subsampling, recurrent, etc. A DNN with convolutional layers is beneficial since the DNN can be deeper based upon the reduced number of parameters.

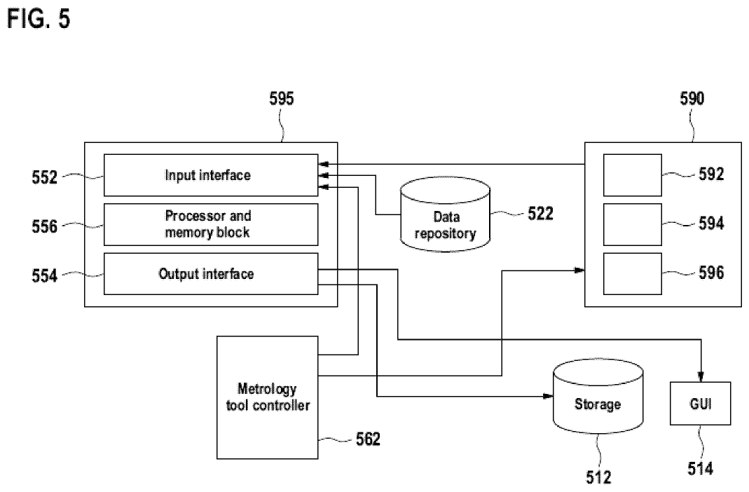

FIG. 5 illustrates a functional block diagram of data processing and control for a system calculating one or more aberration coefficients, particularly including a charged particle beam device or a plurality of charged particle beam devices and for the system for calculating critical dimensioning (CD) information, particularly including a charged particle beam device or a plurality of charged particle beam devices. The controller 590 of the system includes one or more processors 592, one or more memories 594, and may also include a graphical user interface 596. The computer-based system 595 includes an input interface 552 and an output interface 554. Further, a processor and memory block is provided. The data processing can be used for the determining one or more aberration coefficients of a charged particle beam, for example, for inspecting wafers. The data processing system may further be used for a plurality of processing and/or metrology operations. Processing or metrology as used herein includes imaging, inspection of electronic circuits, exposure systems for lithography, detecting systems, defect inspection tools, critical dimensioning tools, and testing systems for integrated circuits.

The computer-based system 595 is capable of automatically aberrations of a charged particle beam in a charged particle beam system, metrology-related values and/or fab-related information. The computer-based system 595 is referred to hereinafter as an FPI (Fabrication Process Information) system. The FPI system can be operatively connected to one or more controllers and/or tools, respectively. FIG. 5 exemplarily shows a manufacturing tool controller 562. The FPI system is further operatively connected to a data repository 522, in which information of the manufacturing fab equipment may be stored.

The FPI system includes a processor and memory block (PMB) 556 operatively connected to an input interface 552, such as a hardware-based input interface and to an output interface 554, such as a hardware-based output interface. PMB 556 is configured to provide processing necessary for operating the FPI system and comprises a processor (not shown separately) and a memory (not shown separately). The processor of PMB 556 can be configured to execute several functional modules in accordance with computer-readable instructions implemented on a non-transitory computer-readable memory comprised in PMB. Such functional modules are referred to hereinafter as comprised in the PMB. Functional modules comprised in the processor include an operatively connected training set generator and a module for a computational model. For example, the computational model may include a neural network, such as a Deep Neural Network (DNN) and/or a Convolutional Neural Network (CNN) as shown in FIG. 4. The module for the computational model is configured to enable data processing using, for example, (deep) neural network(s) for outputting application-specific data (e.g. aberration coefficients) based on the input data.

The FPI system is configured to receive, via input interface 552, data (and/or derivatives thereof) e.g. of one or more charged particle beam devices. The FPI system is further configured to process the received data and send, via output interface 554, the results (or part thereof) to a storage system 512, to tools of the metrology fab equipment, to a computer-based graphical user interface (GUI) 514 for rendering the results, and/or to external systems. GUI 514 can be further configured to enable user-specified inputs related to operating FPI system.

Upon processing the received data (optionally together with other data as, for example, design data) the FPI system can generate a computational model and/or provide aberration coefficients based on a computational model. The results may be sent to any of the tool(s), may be stored in the storage system 512, may be presented via GUI 514 and/or sent to an external system. A person skilled in the art may appreciate that the teachings of the presently disclosed subject matter are not bound by the system illustrated in FIG. 5. Equivalent and/or modified functionality can be consolidated or divided in another manner and can be implemented in any appropriate combination of software with firmware and hardware.

It is noted that the system illustrated in FIG. 5 can be implemented in a distributed computing environment, in which the aforementioned functional modules shown in FIG. 5 can be distributed over several local and/or remote devices, and can be linked through a communication network. Further, the functionality described with respect to FIG. 5 may be distributed differently within the various controllers of the manufacturing fab equipment. At least part of the tools, data repositories, storage system and/or GUI can be external to the manufacturing and/or metrology fab equipment and operate in data communication with the FPI system, e.g. via input interface 552 and output interface 554. The FPI system can be implemented as stand-alone computer(s) to be used in conjunction with one or more of the tools according to embodiments of the present disclosure. The respective functions of the FPI system can, at least partly, be integrated with one or more tool controllers.

It will also be understood that the system according to embodiments described herein may be, at least partly, implemented on a suitably programmed computer. Likewise, embodiments of the present disclosure contemplate a computer program being readable by a computer for executing the method of embodiments of the invention. According to some embodiments of the invention, further a non-transitory computer-readable memory can be provided, tangibly embodying a program of instructions executable by the computer for executing the methods described herein. In accordance with other aspects of the presently disclosed subject matter, there is provided a non-transitory computer readable medium comprising instructions that, when executed by a computer, cause the computer to perform a method of generating a computational model for determining aberrations of a charged particle beam and/or a method of determining beam aberrations of a charged particle beam to embodiments of the present disclosure.

According to some embodiments, which can be combined with other embodiments described herein, a system including a charged particle beam device may include a modelling data processing unit with a further memory 171 comprising further instructions and with a further processor, wherein the further instructions, when executed by the further processor, cause the modelling data processing unit to generate a computational model according to a method of any of claims 1 to 10.

Particularly for training of a computational model, various parameters of a charged particle beam device can be varied to provide a plurality of input data with different parameters. Accordingly, the training of the computational model is based upon a training data set, for which parameters of a charged particle beam device are varied.

According to some embodiments, which can be combined with other embodiments described herein, the plurality of input data is obtained for different sets of a plurality of sets of parameters. The parameters in a set of parameters are one or more parameters selected from the group of: a numerical aperture of the charged particle beam, a beam energy of the charged particle beam, a landing energy of the charged particle beam, a beam current of the charged particle beam, beam brightness of the charged particle beam, beam energy spectrum of the charged particle beam, and deconvolution parameters. For example, the deconvolution parameters can be one or more of a filter size, a filter shape, and a noise level threshold. According to some embodiments, which can be combined with other embodiments described herein, one or more parameters of the set of parameters are obtained and included in the data training data set. One or more of the parameters provided in a training data set may also be provided for a method of determining the one or more aberration coefficients.

According to some embodiments, which can be combined with other embodiments described herein, the deconvolution parameters may include a filter size and/or a filter shape (e.g. a gaussian shape expressed by e −½(x²+y²)/σ² with a size σ. A filter may also be provided by a Wien filter and/or window functions like Tukey window or Hann window, wherein the filters according to embodiments, which can be combined with other embodiments described herein, have a parameter defining a size (see sigma above). A filter in real space is a window in Fourier space and vice versa. Filters in real space reduce or handle the noise of the image data. Windows in real space suppress artifacts from the discontinuous image edges.

According to some embodiments, which can be combined with other embodiments described herein, the numerical aperture as a parameter of a set of parameters as described above, may be calculated from the plurality of images or the plurality of beams spot data of defocus series of the plurality of defocus series. Further, the brightness and/or the energy width as parameters of a set of parameters as described above, may be calculated from the plurality of images or the plurality of beams spot data of defocus series of the plurality of defocus series.

From images taking as a defocus series, i.e. with different defocus settings, one or more beam profiles or beam spot data can be retrieved. Alternatively, beam spot data of a defocus series (different defocus settings) can be utilized. One or more beam profiles at the one or more defocus distances can be simulated based at least on an estimated beam convergence value of the charged particle beam to provide one or more simulated beam profiles. A magnitude (R) of a difference between the one or more simulated beam profiles and the one or more retrieved beam profiles can be determined such that the estimated beam convergence value can be varied in an iterative process for reducing or minimizing said magnitude (R) to determine an actual beam convergence value. In some embodiments, the actual beam convergence value contains information about a change of beam width as a function of defocus distance. In particular, the actual beam convergence value may contain or be the numerical aperture (NA) of the charged particle beam.

Embodiments of the present disclosure relate inter alia to generating a computational model for determining one or more aberration coefficients and to determining one or more aberration coefficients. According to some embodiments, which can be combined with other embodiments described herein, the one or more aberration coefficients for each of the plurality of aberration coefficients can be selected from the group consisting of: spherical aberration (Cs or C3,0), chromatic aberration (Cc), defocus (Cdf), astigmatism of 1^{st} order (C1,2 or Cast-2 fold), astigmatism of 2^{nd} order (C2,3 or Cast,3-fold), astigmatism of 3^{rd} order (C3,4 or Cast,4-fold), coma (Ccoma), and Star (C3,2 or Cstar).

A plurality of chromatic aberrations may be present, depending on the energy spread of the charged particle beam and on the dispersion of the beam-optical components of the system, which can be quantitatively expressed by one or more chromatic aberration coefficients.

A set of beam aberration coefficients C_{1 . . . n} may include two, three or more of the above beam aberration coefficients, for example C_{1 . . . n}=[C_{df}, Cₛ, A₁, A₂]. According to some embodiments, which can be combined with other embodiments described herein, a computational model can be generated for one aberration coefficient. The computation model can be trained for a set of aberration coefficients and the set of coefficients, particularly the same set of coefficients can be determined with the computational model. One or more computational models can be generated for one aberration coefficient each. Alternatively, a computational model can be generated for a plurality of aberration coefficients, i.e. a set of aberration coefficients. Further, a combination of having a computational model for first group (with a number of n>=1) aberration coefficients and one or more second groups (with numbers of n>=1) of aberration coefficients, can be provided.

According to an embodiment, which can be combined with other embodiments described herein, a method of determining one or more aberration coefficients of a charged particle beam focused by a focusing lens towards a specimen is provided. The method includes providing a plurality of images of a defocus series. Particularly, providing the images may include imaging the plurality of images with a charged particle beam device, such as a SEM. The plurality of images or a plurality of beam spot data retrieved from the plurality of images are provided in a computational model associating the defocus series with one or more aberration coefficients. The computation model is generated by machine learning. The method further includes obtaining one or more aberrations coefficients from the computational model. Particularly, the one or more aberration coefficients can be absolute values of aberration coefficients.

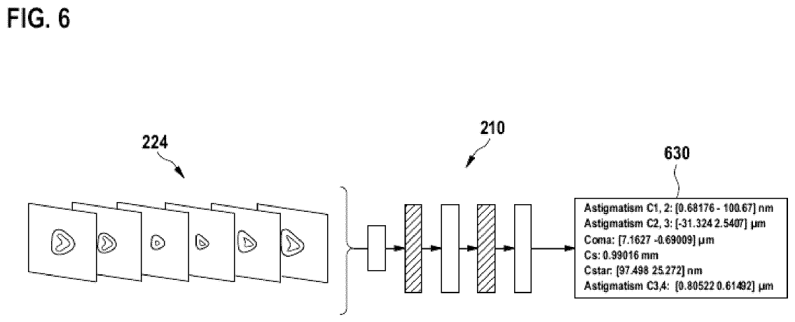

FIG. 6 shows a diagram exemplarily explaining a method of determining aberration coefficients. Beam spot data 224 of a defocus series is provided. The beam spot data 224 of the defocus series provides beam spot information for several defocus settings. The beam spot data is provided in a computational model, such as a neural network 210. The neural network 210, which may previously be generated according to embodiments of the present disclosure, provides one or more aberration coefficients 630 as result based on the beam spot data. According to some embodiments, which can be combined with other embodiments described herein, parameters of a set of parameters, such as landing energy, numerical aperture, filter site, or others, may also be provided as an input for the computational model.

According to some embodiments, which can be combined with other embodiments described herein, a plurality of images of defocus areas can be provided as an input in the computational model, particularly in the event the computational model has been trained with images. According to some embodiments, which can be combined with other embodiments described herein, the computational model can be generated with the method according to any of the embodiments described herein.

For embodiments, in which a set of parameters has been provided for the training data set when generating the computational model, a set of parameters (not shown in FIG. 6) can be provided as further input in the computational model, the parameters in a set of parameters can be one or more selected from the group consisting of: a numerical aperture, a beam energy, a landing energy, a beam current, beam brightness, beam energy spectrum, and deconvolution parameters. For example, the deconvolution parameters can be one or more of a filter size, a filter shape, and a noise level threshold.

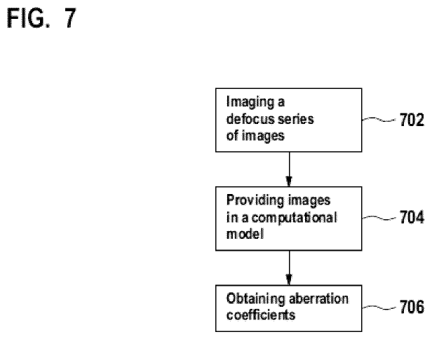

FIG. 7 shows a flowchart illustrating a method of determining one or more aberration coefficients of a charged particle beam. Images of a specimen are obtained, wherein the images provide a defocus series of a region of the specimen (see, e.g. operation 702). Images of the sample are taken at the different defocus settings to provide one or more taken images. In particular, the defocus settings may include the different defocus distances (zₒ₋₁, zᵤ₋₁) from a respective beam focus of the charged particle beam, such that the one or more images of the sample are taken when the sample is arranged at the one or more defocus distances from the beam focus, as it is schematically illustrated in FIG. 1. The defocus settings may additionally or alternatively include different focusing strength or may include different landing energies. At operation 704, the images are provided in a computational model. The computational model associates the defocus series with one or more aberration coefficients. The computational model has been trained by machine learning. For example, the computational model has been trained according to any of the embodiments of the present disclosure and/or the computational model can be any computational model according to embodiments of the present disclosure. From the computational model, one or more aberration coefficients are obtained at operation 706.

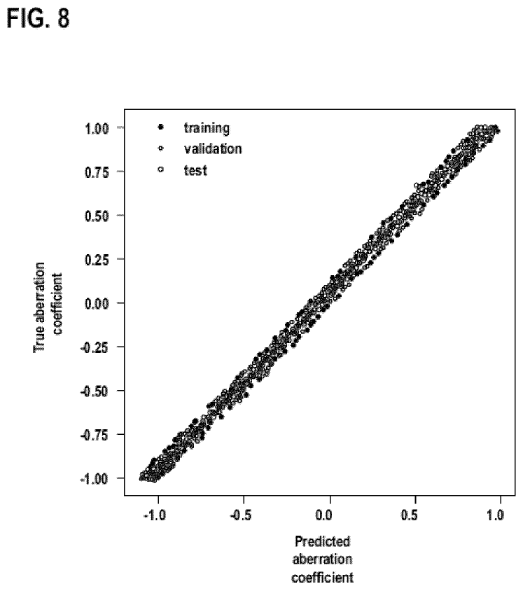

FIG. 8 shows the results of a method of generating a computational model for determining one or more aberration coefficients of a charged particle beam and a method of determining one or more aberration coefficients of a charged particle beam. FIG. 8 shows an example of one aberration coefficient. Similar results have been obtained for other aberration coefficients. A set of simulated beam spot data for known aberration coefficients has been used. The simulated data has been separated into three groups, namely training input data, validation input data and test input data. A CNN has been trained with the test input data to adjust the weights of the neural network. The validation input data has been used to determine the end of the training, i.e. the best time to stop training. The validation input data was not used to update or train the weights of the network. The test input data has not been used during training but for verification of the computational model after training. As can be seen in FIG. 8, each of the training input data, validation input data, and test input data shows a good fit of the graphs, wherein the true aberration coefficient and the predicted aberration coefficient, i.e. the aberration coefficient determined with the computational model are plotted against each other. For each of the groups of input data, the coefficient of determination r² is 0.999, 0.998 or 0.998 respectively.

Embodiments of the present disclosure utilizing machine learning algorithms or artificial intelligence for determining one or more aberration coefficients may further be enhanced to computational models for critical dimensioning (CD) measurements. Particularly, computational model for a CD measurement can be generated and CD information can be obtained from a charged particle beam image. According to some embodiments, which can be combined with other embodiments described herein, a computational model for determining aberration information can be used for a computational model for CD information.

According to an embodiment, a method of generating a computation model for a CD measurement is provided. The method includes obtaining a plurality of CD images. Further, the method includes obtaining a plurality of aberration spot information and obtaining a plurality of sets of parameters. For generating a training data set, the method includes obtaining a plurality of CD correlation information. A training data set is generated from the plurality CD images, the plurality of aberration spot information, the plurality of sets of parameters, and the plurality of CD information. The computational model is produced or generated by machine learning from the training data set.

A computational model can be generated by providing sets of images e.g. with different parameters and having target CD information for training. A loss function can be minimized for training, and particularly having at least one component of a loss function relating to tool matching, i.e. relating to matching different charged particle beam devices (e.g. SEMs), to provide the same or similar CD information. The parameters can be set for each metrology algorithm. According to some embodiments, which can be combined with other embodiments described herein, parameters may be one or more selected from: parameters selected from the group consisting of: a numerical aperture, a beam energy, a landing energy, a beam current, beam brightness, beam energy spectrum, and deconvolution parameters.

According to embodiments of the present disclosure, in addition to a set of parameters, aberration spot information is provided for determining CD information or training corresponding computational model. A set of beam aberration coefficients C1 . . . n may include two, three or more of the above beam aberration coefficients, for example C1 . . . n=[Cdf, Cs, C1,2, C2,3]. The absolute values of the beam aberration coefficients of the set of beam aberration coefficients C1 . . . n is utilized according to embodiments and methods described herein.

Accordingly, a training data set includes a plurality of CD images and a plurality of aberration spot information, wherein each of the plurality of aberration spot information is selected from the group consisting of: images of defocus series, beam spot data of defocus series, and one or more aberration coefficients. Further, the training data set includes a plurality of sets of parameters and a plurality of CD correlation information, i.e. the true CD information for the training.

According to some embodiments, which can be combined with other embodiments described herein, the one or more aberration coefficients can be determined by a method according to any of the embodiments described herein, particularly described with respect to FIGS. 1 to 8.

CD correlation information can be provided by measuring the plurality of CD images with the same sample for at least one of different aberration spot information and different sets of parameters. For example, measuring the plurality of CD images with the same sample is provided by measuring with two or more charged particle beam devices. CD correlation between different tools or between different conditions for one tool can be provided by imaging the same CD image under different conditions. Additionally or alternatively, the plurality of CD correlation information can be provided by CD information of to the plurality of CD images for different samples. For example, known CD information values can be provided for different samples.

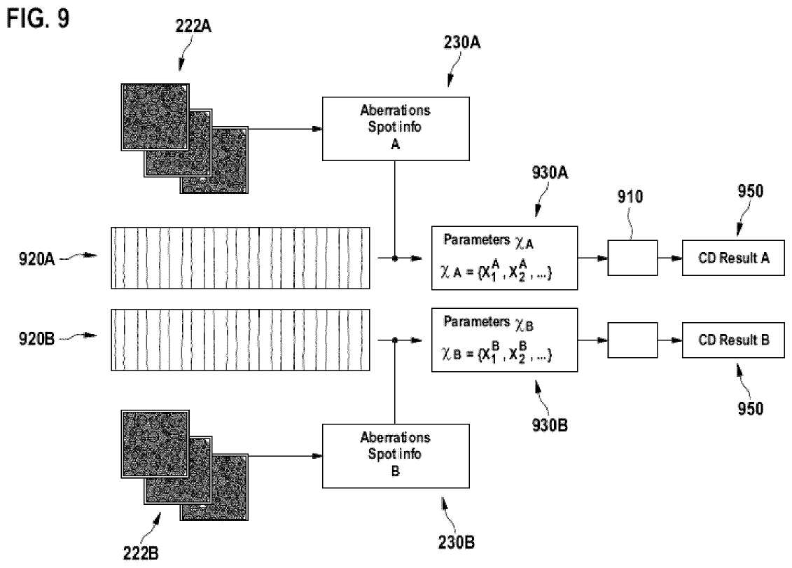

FIG. 9 shows a diagram illustrating methods for determining CD information according to embodiments of the present disclosure. For example, an image 920A, such as an image for CD measurement, can be obtained with the first tool, i.e. the first charged particle beam device, such as a first SEM.

Additionally, images of the first defocus series 222A, are provided with the first tool. Aberration spot information 230A is obtained from the images of the first defocus series 222A. According to some embodiments, which can be combined with other embodiments described herein, the aberration spot information 230A of the first tool may be provided by other methods or may be known. The aberration spot information includes absolute values of beam aberration coefficients, i.e. as the actual quantitative values of the beam aberration coefficients, such as Cs expressed in [mm]. An absolute value is a numerical value, which can be positive or negative. Further, a set of parameters 930A for the image 920A is provided. The aberration spot information 230A and the set of parameters 930A is provided together with the image 920A in a computational model 910. The computational model provides CD information, i.e. a CD results 950, which has been measured with the first tool.

Since the computational model 910 has been trained with different sets of parameters and the plurality of aberration spot information, an improved matching between CD results of, for example, a first tool and a second tool can be provided. FIG. 9 shows the example of an image 920B of the same structure on the same sample obtained with a second tool, i.e. a second, SEM and images of the first defocus series 222B of the second tool. The aberration spot information 230B of the second tool can be provided with the second set of parameters 930B in the computational model 910 for obtaining CD results 95. In light of the tool matching, the CD results from the first tool and the second tool of the same structure, provide the same or similar results. Accordingly, CD results can be more reliably provided irrespective of the tool used. A similar consideration also applies for images taken on the same tool but under different conditions, e.g. at different points in time.

According to an embodiment, a method of determining CD information of a charged particle beam image is provided. The method includes generating an image of a specimen; obtaining one or more aberration coefficients; obtaining a set of parameters; and generating CD results from a computational model with the image, the one or more aberration coefficients, and the set of parameters as an input for the computational model. According to some embodiments, which can be combined with other embodiments described herein, the one or more aberration coefficients are determined by a method of any of the embodiments described herein, and as exemplarily illustrated in FIG. 9. Alternatively, the aberration coefficients, particularly upon generation of the CD image, can be known or can be determined by other methods, for example, iterative determination based upon matching with simulated beam spot data.

The present disclosure provides a plurality of embodiments, some of which are listed below. Embodiment 1. A method of generating a computational model for determining one or more aberration coefficients of a charged particle beam focused by a focusing lens towards a specimen, comprising: obtaining a plurality of input data associated with a plurality of beam spot information for a plurality of defocus settings; obtaining a plurality of one or more aberrations coefficients associated with corresponding input data of the plurality of input data; providing a training data set including the plurality of aberrations coefficients and the corresponding input data; and producing or generating the computational model by machine learning from the training data set.

Embodiment 2. The method of embodiment 1, wherein the plurality of input data is a plurality of images of defocus series, the images being from a charged particle beam device, and particularly to obtain the plurality of beam spot information from the plurality of images.

Embodiment 3. The method of embodiment 2, wherein the plurality of images are converted into a plurality of beam spot data with a deconvolution operation.

Embodiment 4. The method of embodiment 2, wherein the plurality of images are converted into a plurality of beam spot data by dividing images of the plurality of images in Fourier space.

Embodiment 5. The method of embodiment 1, wherein the plurality of input data is a plurality of beam spot data of defocus series.

Embodiment 6. The method of embodiment 5, wherein the plurality of beam spot data is calculated from images that are measured with a charged particle beam device.

Embodiment 7. The method of embodiment 5, wherein the plurality of beam spot data and the plurality of one or more aberration coefficients are simulated.

Embodiment 8. The method of any of embodiments 1 to 7, wherein the plurality of input data is obtained for different sets of a plurality of sets of parameters, the parameters in a set of parameters selected from the group consisting of: a numerical aperture of the charged particle beam, a beam energy of the charged particle beam, a landing energy of the charged particle beam, a beam current of the charged particle beam, beam brightness of the charged particle beam, beam energy spectrum of the charged particle beam, and deconvolution parameters.

Embodiment 9. The method of embodiment 8, wherein one or more parameters of the set of parameters are obtained and included in the data training data set.

Embodiment 10. The method of any of embodiments 8 to 9, wherein the numerical aperture is calculated from the input data for the plurality of defocus settings.

Embodiment 11. The method of any of any of embodiments 1 to 10, wherein the one or more aberration coefficients for each of the plurality of aberration coefficients are selected from the group consisting of: spherical aberration (Cs or C3,0), chromatic aberration (Cc), defocus (C1,0 or Cdf), astigmatism of 1st order (C1,2 or Cast-2 fold), astigmatism of 2nd order (C2,3 or Cast,3-fold), astigmatism of 3rd order (C3,4 or Cast,4-fold), coma (Ccoma), and Star (C3,2 or Cstar).

Embodiment 12. A method of determining one or more aberration coefficients of a charged particle beam focused by a focusing lens towards a specimen, comprising: providing a plurality of images of a defocus series, the images are of a charged particle beam device; providing the plurality of images or a plurality of beam spot data retrieved from the plurality of images in a computational model associating the defocus series with one or more aberration coefficients, the computation model being generated by machine learning; and obtaining one or more aberrations coefficients from the computational model.

Embodiment 13. The method of embodiment 12, wherein the one or more aberration coefficients are absolute values of aberration coefficients.

Embodiment 14. The method of any of embodiments 12 to 13, wherein the computation model is generated with a method of any of embodiments 1 to 10.

Embodiment 15. The method of any of embodiments 12 to 14, further comprising: providing a set of parameters as further input in the computational model, the parameters in a set of parameters selected from a group of: a numerical aperture, a beam energy, a landing energy, a beam current, beam brightness, beam energy spectrum, and deconvolution parameters.

Embodiment 16. The method of any of embodiments 12 to 16, wherein providing the plurality of images of a defocus series comprises: imaging a plurality of images of a defocus series with the charged particle beam device.

Embodiment 17. A method of generating a computation model for a CD measurement, comprising: obtaining a plurality of CD images; obtaining a plurality of aberration spot information; obtaining a plurality of sets of parameters; obtaining a plurality of CD correlation information; generating a training data set from the plurality CD images, the plurality of aberration spot information, the plurality of sets of parameters, and the plurality of CD information; and producing or generating the computational model by machine learning from the training data set.

Embodiment 18. The method of embodiment 17, wherein each of the plurality of aberration spot information is selected from the group consisting of: images of defocus series, beam spot data of defocus series, and one or more aberration coefficients.

Embodiment 19. The method of any of embodiments 17 to 18, wherein the one or more aberration coefficients are determined by a method of any of embodiments 9 to 11.

Embodiment 20. The method of any of embodiments 17 to 19, wherein the plurality of CD correlation information is provided by measuring the plurality of CD images with the same sample for at least one of different aberration spot information and different sets of parameters.

Embodiment 21. The method of embodiment 20, wherein the measuring the plurality of CD images with the same sample is provided by measuring with two or more charged particle beam devices.

Embodiment 22. The method of any of embodiments 17 to 19, wherein the plurality of CD correlation information is provided by CD information of to the plurality of CD images for different samples.

Embodiment 23. A method of determining CD information of a charged particle beam image, comprising: generating an image of a specimen with a charged particle beam device; obtaining one or more aberration coefficients; obtaining a set of parameters; and generating CD results from a computational model with the image, the one or more aberration coefficients, and the set of parameters as an input for the computational model.

Embodiment 24. The method of embodiment 23, wherein the one or more aberration coefficients are determined by a method of any of embodiments 12 to 16.

Embodiment 25. A system for calculating one or more aberration coefficients, comprising: a memory comprising instructions; and a processor executing the instructions to determine aberration coefficients with a method of any of embodiments 12 to 16.

Embodiment 26. The system of embodiment 25, wherein the system further includes a charged particle beam device.

Embodiment 27. A system for calculating CD information, comprising: a memory comprising instructions; and a processor executing the instructions to determine aberration coefficients with a method of any of embodiments 23 to 24.

Embodiment 28. The system of embodiment 27, wherein the system further includes a charged particle beam device.

While the foregoing is directed to embodiments, other and further embodiments may be devised without departing from the scope thereof, and the scope thereof is determined by the claims that follow.

1. A method of generating a computational model for determining one or more aberration coefficients of a charged particle beam focused by a focusing lens towards a specimen, comprising:
obtaining a plurality of input data associated with a plurality of beam spot information for a plurality of defocus settings;
obtaining a plurality of one or more aberrations coefficients associated with corresponding input data of the plurality of input data;
providing a training data set including the plurality of one or more aberrations coefficients and the corresponding input data; and
producing or generating the computational model by machine learning from the training data set.

2. The method of claim 1, wherein the plurality of input data is a plurality of images of defocus series, the images being from a charged particle beam device, and particularly to obtain the plurality of beam spot information from the plurality of images.

3. The method of claim 2, wherein the plurality of images are converted into a plurality of beam spot data with a deconvolution operation.

4. The method of claim 2, wherein the plurality of images are converted into a plurality of beam spot data by dividing images of the plurality of images in Fourier space.

5. The method of claim 1, wherein the plurality of input data is a plurality of beam spot data of defocus series.

6. The method of claim 5, wherein the plurality of beam spot data is calculated from images that are measured with a charged particle beam device.

7. The method of claim 5, wherein the plurality of beam spot data and the plurality of one or more aberration coefficients are simulated.

8. The method of claim 1, wherein the plurality of input data is obtained for different sets of a plurality of sets of parameters, the parameters in a set of parameters selected from the group consisting of: a numerical aperture of the charged particle beam, a beam energy of the charged particle beam, a landing energy of the charged particle beam, a beam current of the charged particle beam, beam brightness of the charged particle beam, beam energy spectrum of the charged particle beam, and deconvolution parameters.

9. The method of claim 8, wherein one or more parameters of the set of parameters are obtained and included in the training data set.

10. The method of claim 8, wherein the numerical aperture is calculated from the input data for the plurality of defocus settings.

11. The method of claim 1, wherein the one or more aberration coefficients for each of the plurality of one or more aberration coefficients are selected from the group consisting of: spherical aberration (Cs or C3,0), chromatic aberration (Cc), defocus (C1,0 or Cdf), astigmatism of 1st order (C1,2 or Cast-2 fold), astigmatism of 2nd order (C2,3 or Cast,3-fold), astigmatism of 3rd order (C3,4 or Cast,4-fold), coma (Ccoma), and Star (C3,2 or Cstar).

12. A method of determining one or more aberration coefficients of a charged particle beam focused by a focusing lens towards a specimen, comprising:
providing a plurality of images of a defocus series, the images are of a charged particle beam device;
providing the plurality of images or a plurality of beam spot data retrieved from the plurality of images in a computational model associating the defocus series with one or more aberration coefficients, the computation model being generated by machine learning; and
obtaining one or more aberrations coefficients from the computational model.

13. The method of claim 12, wherein the one or more aberration coefficients are absolute values of aberration coefficients.

14. The method of claim 12, wherein the computation model is generated by a method that comprises:
obtaining a plurality of input data associated with a plurality of beam spot information for a plurality of defocus settings;
obtaining a plurality of one or more aberrations coefficients associated with corresponding input data of the plurality of input data;
providing a training data set including the plurality of one or more aberrations coefficients and the corresponding input data; and
producing or generating the computational model by machine learning from the training data set.

15. The method of claim 12, further comprising:
providing a set of parameters as further input in the computational model, the parameters in a set of parameters selected from a group of: a numerical aperture, a beam energy, a landing energy, a beam current, beam brightness, beam energy spectrum, and deconvolution parameters.

16. The method of claim 12, wherein providing the plurality of images of a defocus series comprises:
imaging a plurality of images of a defocus series with the charged particle beam device.

17. A method of generating a computation model for a CD measurement, comprising:
obtaining a plurality of CD images;
obtaining a plurality of aberration spot information;
obtaining a plurality of sets of parameters;
obtaining a plurality of CD correlation information;
generating a training data set from the plurality of CD images, the plurality of aberration spot information, the plurality of sets of parameters, and the plurality of CD correlation information; and
producing or generating the computational model by machine learning from the training data set.

18. The method of claim 17, wherein each of the plurality of aberration spot information is selected from the group consisting of: images of defocus series, beam spot data of defocus series, and one or more aberration coefficients.

19. The method of claim 18, wherein the one or more aberration coefficients are determined by a method that comprises:
obtaining a plurality of input data associated with a plurality of beam spot information for a plurality of defocus settings;
obtaining a plurality of one or more aberrations coefficients associated with corresponding input data of the plurality of input data;
providing a training data set including the plurality of one or more aberrations coefficients and the corresponding input data; and
producing or generating the computational model by machine learning from the training data set,
wherein the plurality of input data is obtained for different sets of a plurality of sets of parameters, the parameters in a set of parameters selected from the group consisting of: a numerical aperture of a charged particle beam, a beam energy of the charged particle beam, a landing energy of the charged particle beam, a beam current of the charged particle beam, beam brightness of the charged particle beam, beam energy spectrum of the charged particle beam, and deconvolution parameters, and
wherein one or more parameters of the set of parameters are obtained and included in the training data set.

20. The method of claim 17, wherein the plurality of CD correlation information is provided by measuring the plurality of CD images with the same sample for at least one of different aberration spot information and different sets of parameters.

21. The method of claim 20, wherein the measuring the plurality of CD images with the same sample is provided by measuring with two or more charged particle beam devices.

22. The method of claim 17, wherein the plurality of CD correlation information is provided by CD information of to the plurality of CD images for different samples.

23. A method of determining CD information of a charged particle beam image, comprising:
generating an image of a specimen with a charged particle beam device;
obtaining one or more aberration coefficients;
obtaining a set of parameters; and
generating CD results from a computational model with the image, the one or more aberration coefficients, and the set of parameters as an input for the computational model.

24. The method of claim 23, wherein the one or more aberration coefficients are determined by a method that comprises:
providing a plurality of images of a defocus series, the images are of a charged particle beam device;
providing the plurality of images or a plurality of beam spot data retrieved from the plurality of images in a computational model associating the defocus series with one or more aberration coefficients, the computation model being generated by machine learning; and
obtaining one or more aberrations coefficients from the computational model.

25. A system for calculating one or more aberration coefficients, comprising:
a memory comprising instructions; and
a processor executing the instructions to determine aberration coefficients with a method of claim 12.

26. The system of claim 25, wherein the system further includes a charged particle beam device.

27. A system for calculating CD information, comprising:
a memory comprising instructions; and
a processor executing the instructions to determine aberration coefficients with a method of claim 23.

28. The system of claim 27, wherein the system further includes a charged particle beam device.
